(19) United States
(12) Patent Application Publication
(10) Pub. No.: US 2001/0044191 A1
(43) Pub. Date: Nov. 22, 2001

(54) METHOD FOR MANUFACTURING SEMICONDUCTOR DEVICE

(76) Inventors: SHIANG HUANG-LU, HSINCHU (TW); MU-CHUN WANG, HSINCHU HSIEN (TW)

Correspondence Address: J C Patents Inc, 4 Venture, Suite 250, Irvine, CA, 92618, US

(21) Appl. No.: 09/235,061

(22) Filed: Jan. 20, 1999

(51) Int. Cl. H01L 21/336; H01L 21/425

(52) U.S. Cl. 438/305; 438/529

(57) ABSTRACT

A method for manufacturing semiconductor device includes the steps of providing a substrate that has a gate electrode thereon, and then forming a dielectric layer over the substrate. The dielectric layer is conformal to the profile of the substrate and has a definite thickness. Thereafter, using the gate electrode and that portion of the dielectric layer next to the sidewalls of the gate electrode as a mask, a first ion implantation is carried out. Hence, a doped drain region is formed in the substrate and a channel region is formed in the substrate just under the gate electrode. Subsequently, spacers are formed over the exposed dielectric layer next to the sidewalls of the gate electrode. Finally, using a portion of the dielectric layer next to the sidewalls of the gate electrode and the spacers as a mask, a second ion implantation is carried out. Hence, source/drain regions are formed in the substrate on each side of the gate electrode.

### BACKGROUND OF THE INVENTION

1. Field of Invention

The present invention relates to a method for manufacturing semiconductor devices. More particularly, the present invention relates to a method for manufacturing metal oxide semiconductor (MOS) devices.

2. Description of Related Art

As the techniques for manufacturing semiconductors continue to advance, semiconductor devices having a smaller line width can be fabricated on a larger wafer. Hence, each generation of integrated circuits has more functions but costs less. At present, semiconductor devices have miniaturized to the sub-quarter micron (0.25 μm) dimension. However, accompanying the reduction in line width, channel length of the MOS device is correspondingly reduced. Therefore, problems related to having a short channel, such as the short channel effect and the hot carrier effect, are intensified.

One method of reducing the severity of short channel effect and hot carrier effect is to carry out two separate doping operations to form the source/drain regions of a MOS device. First, substrate areas next to the channel region of a MOS device are doped to form a lightly doped region. Then, substrate areas further away from the lightly doped region are doped to form a heavily doped region. The heavily doped regions reach a depth greater than the lightly doped regions. This type of structural design is known as a lightly doped drain (LDD). Besides building a LDD structure, a moderately doped drain (MDD) structure and a heavily doped drain (HDD) can also be manufactured. Here, the LDD structure is used as an example throughout.

FIGS. 1A through 1D are schematic, cross-sectional views showing the progression of manufacturing steps according to a conventional method of producing the lightly doped drain structure of a MOS device.

First, as shown in FIG. 1A, a substrate 100 having a gate oxide layer 104 and a gate electrode 102 thereon is provided. Thereafter, using the gate electrode 102 as a mask, a first implantation 108 is carried out. In the first implantation 108, arsenic or phosphorus (opposite in ionic type to the dopants in the substrate), for example, are implanted into the substrate 100 to form a lightly doped drain (LDD) region 110.

Next, as shown in FIG. 1B, spacers 112 are formed on the sidewalls of the gate electrode 102. The spacers 112 can be formed by depositing a silicon dioxide layer over the substrate 100 using a chemical vapor deposition (CVD) method, and then performing an anisotropic etching operation to etch back the silicon dioxide layer.

Next, as shown in FIG. 1C, using the spacers 112 and the gate electrode 102 as a mask, a second ion implantation 114 is performed. In the second implantation 114, arsenic or phosphorus ions of higher concentration are implanted into the substrate 100 to form a heavily doped region within the lightly doped drain region 110. Hence, source/drain regions 116 having LDD structure are formed.

The aforementioned method of forming LDD structures encounters more problems as the level of integration for MOS devices increases. For example, as shown in FIG. 1D, a MOS device with a LDD source/drain region 116 has a very small width 120. Therefore, it is difficult to control the distribution of dopants in the first ion implantation. Furthermore, dopants within the lightly doped region 110 tend to diffuse into the channel region during subsequent thermal operations (for example, annealing operations), thereby further reducing the channel length of a MOS device. Consequently, the short channel effect is amplified. In addition, a portion of the lightly doped drain region 110 that lies underneath the gate electrode 102 (the diffusion region 118 as shown in FIG. 1D) also forms a conductor/dielectric/conductor type of capacitor structure together with the gate electrode 102 and the gate oxide layer 104. The capacitor having a gate-to-drain (source) capacitance Cgd (Cgs) can reduce the effectiveness of AC performance and increase the gate-switching response time.

In light of the foregoing, there is a need to provide a better method for fabricating a MOS device.

### SUMMARY OF THE INVENTION

Accordingly, the purpose of the present invention is to provide a method for manufacturing a semiconductor device capable of preventing a hot carrier effect and a short channel effect due to ions diffusing from the lightly doped drain region into the substrate area underneath the gate electrode when deep-submicron devices are fabricated.

A second aspect of the invention is to provide a method for manufacturing a semiconductor device capable of preventing the formation of a gate-to-drain capacitor in the MOS device due to ions diffusing from the lightly doped drain (source) region into the substrate area underneath the gate electrode, and hence leading to a lowering of device efficiency.

To achieve these and other advantages and in accordance with the purpose of the invention, as embodied and broadly described herein, the invention provides a method for manufacturing a semiconductor device. The method includes the steps of providing a substrate that has a gate electrode thereon, and then forming a dielectric layer over the substrate. The dielectric layer is conformal to the substrate profile and has a definite thickness. Thereafter, using the gate electrode and the dielectric layer attached to the sidewalls of the gate electrode as a mask, a first ion implantation is carried out. Hence, a doped drain region is formed in the substrate and a channel region is formed in the substrate just underneath the gate electrode. Subsequently, spacers are formed over the exposed dielectric layer over the sidewalls of the gate electrode. Finally, using the dielectric layer over the sidewalls of the gate electrode and the spacers as a mask, a second ion implantation is carried out. Hence, source/drain regions are formed in the substrate on each side of the gate electrode.

According to a second embodiment, the invention provides a method for manufacturing semiconductor device. The method includes the steps of providing a substrate that has a gate electrode thereon, and then forming first spacers on the sidewalls of the gate electrode. The first spacers have a definite thickness. Thereafter, using the gate electrode and the first spacers as a mask, a first ion implantation is carried out. Hence, a lightly doped drain region is formed in the substrate and a channel region is formed in the substrate just underneath the gate electrode. Next, second spacers are formed on the exterior sidewalls of the first spacers. Finally, using the gate electrode, the first spacers and the second spacers as a mask, a second ion implantation is carried out to form source/drain regions in the substrate.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIGS. 1A through 1D are schematic, cross-sectional views showing the progression of manufacturing steps according to a conventional method of producing the lightly doped drain structure of a MOS device;

FIGS. 2A through 2E are schematic, cross-sectional views showing the progression of manufacturing steps for producing a semiconductor device according to a first preferred embodiment of the invention; and

FIGS. 3A through 3D are schematic, cross-sectional views showing the progression of manufacturing steps for producing a semiconductor device according to a second preferred embodiment of the invention.

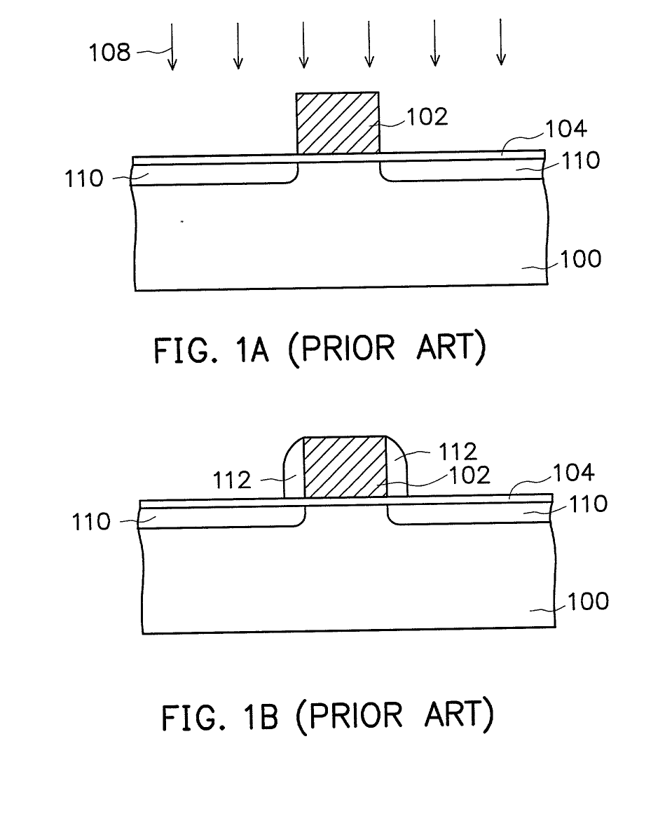

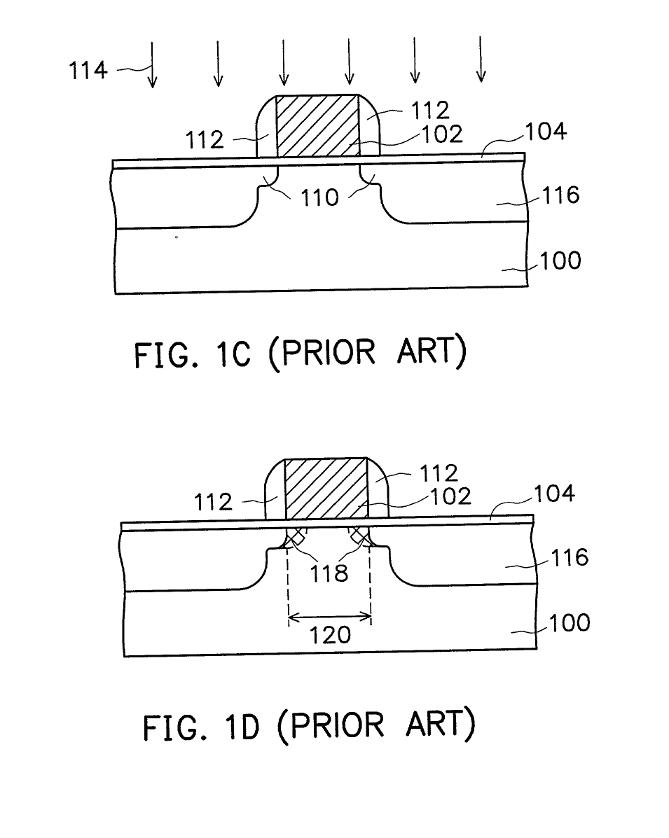

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

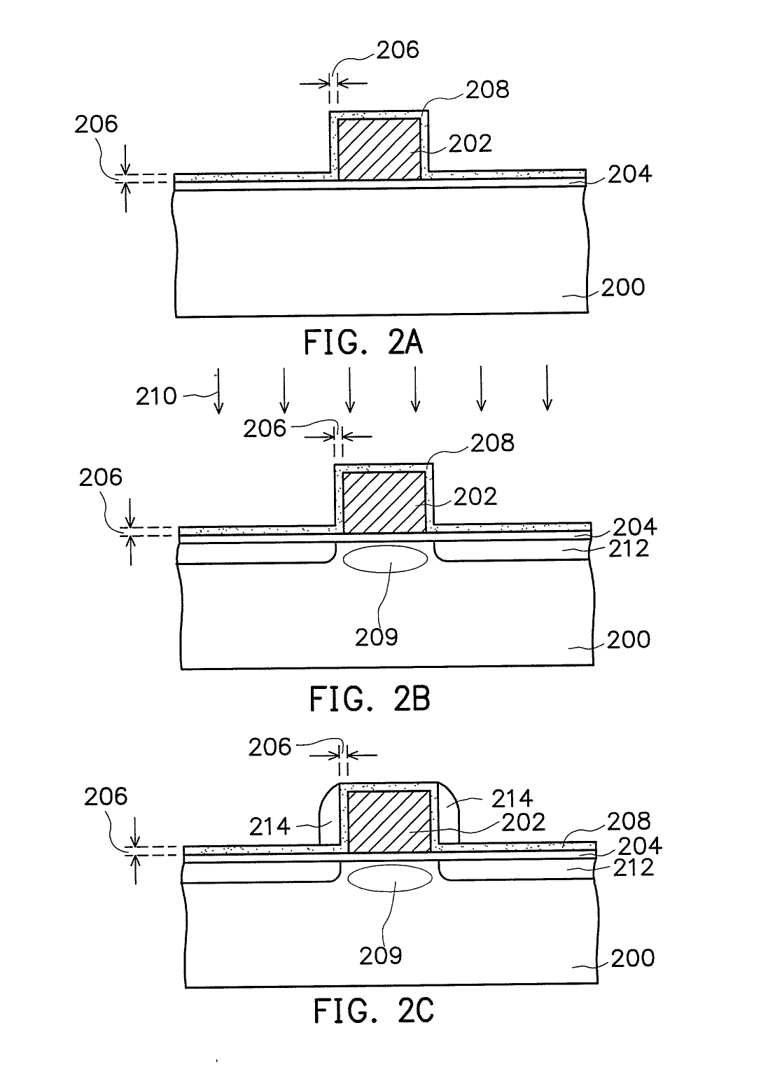

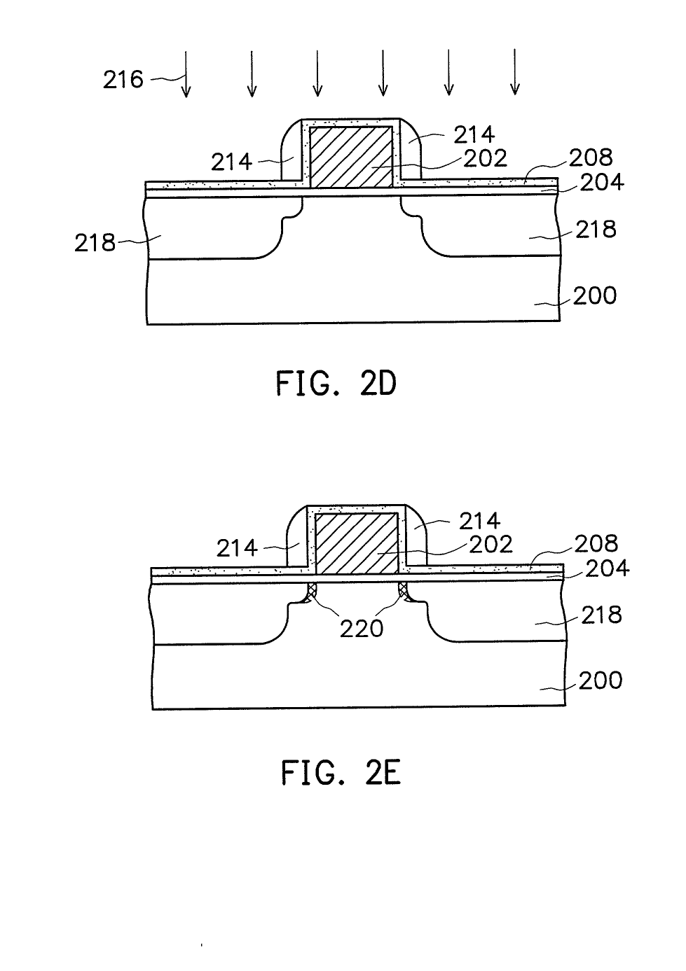

FIGS. 2A through 2E are schematic, cross-sectional views showing the progression of manufacturing steps for producing a semiconductor device according to a first preferred embodiment of the invention.

In this invention, the fabrication of an NMOS device is used as an illustration. However, the method can be similarly applied to the fabrication of a PMOS device. First, as shown in FIG. 2A, a substrate 200 having a gate oxide layer 204 and a gate electrode 202 is provided. Thereafter, a dielectric layer 208 is formed over the substrate 200 and the gate electrode 202. Thickness 206 of the dielectric layer 208 depends on the required channel length. Preferably, the dielectric layer 208 is a silicon nitride layer formed using, for example, a chemical vapor deposition (CVD) method.

A first ion implantation 210 is carried out implanting, for example, arsenic or phosphorus ions into the substrate 200 to form lightly doped regions 212 as shown in FIG. 2B. Concentration of ions in the first ion implantation 210 can be adjusted according to the specific requirement. Consequently, a source/drain region having a lightly doped drain (LDD) structure, moderately doped drain (MDD) structure or a heavily doped drain (HDD) structure are formed.

Since that portion of the dielectric layer 208 attached to the sidewalls of the gate electrode 202 has greater height, the gate electrode 202 and the sidewall-attached portion of the dielectric layer 208 can serve as a mask. The mask prevents ions in the first ion implantation 210 from entering the substrate area underneath the gate electrode 202, hence forming a channel region 209 in the substrate there.

Since the maximum distance traveled by ions from within the lightly doped drain region 212 is quite limited, the extra traveling distance of ions provided by the dielectric layer 208 is able to prevent the ions in the lightly doped drain region 212 from entering into the substrate 200 area underneath the gate electrode 202. Hence, gate-to-drain capacitance (Cgd) formed by the elements that include the gate electrode 202, the gate oxide layer 204 and the lightly doped drain region 212 can be reduced considerably. Furthermore, by controlling the thickness 206 of the dielectric layer 208, length of the channel 209 can be adjusted to reduce the short channel effect.

As shown in FIG. 2C, spacers 214 are formed over the dielectric layer 208 on the sidewalls of the gate electrode 202. The spacers 214 can be formed, for example, by first depositing a silicon dioxide layer over the substrate 200 using a chemical vapor deposition (CVD) method. Thereafter, an anisotropic etching operation is conducted to etch back some of the silicon dioxide material.

As shown in FIG. 2D, using both the spacers 214 and the gate electrode 202 as a mask, a second ion implantation 216 is performed. Finally, source/drain regions 218 each having a lightly doped drain region 212 are formed.

In the conventional method, although a gate oxide layer is formed over the substrate for protecting the substrate surface so that the substrate will be less vulnerable to damage during ion implantation, the gate oxide layer tends to trap ions. These trapped ions can easily diffuse from the gate oxide layer into the substrate or the gate electrode leading to the generation of leakage current in the device. However, in the first embodiment of the invention, the dielectric layer 208 also covers the substrate 200 beside the gate electrode 202. Hence, when the first or the second ion implantation is carried out, the dielectric layer 208 is able to protect the substrate 200 and the gate oxide layer 204. Thus, fewer ionic damages in the substrate will be produced, and the quantities of trapped ions within the substrate are reduced, too.

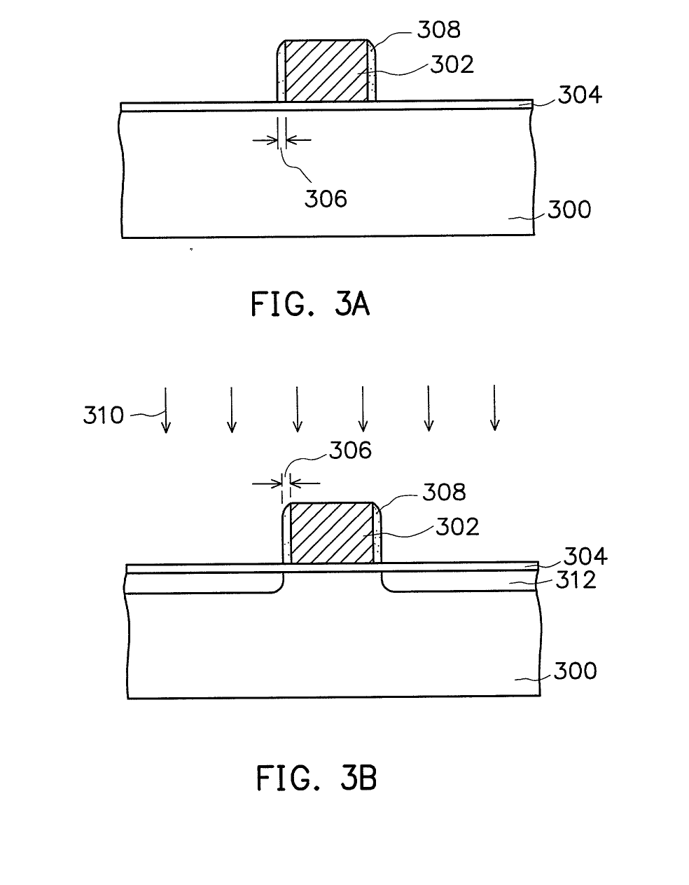

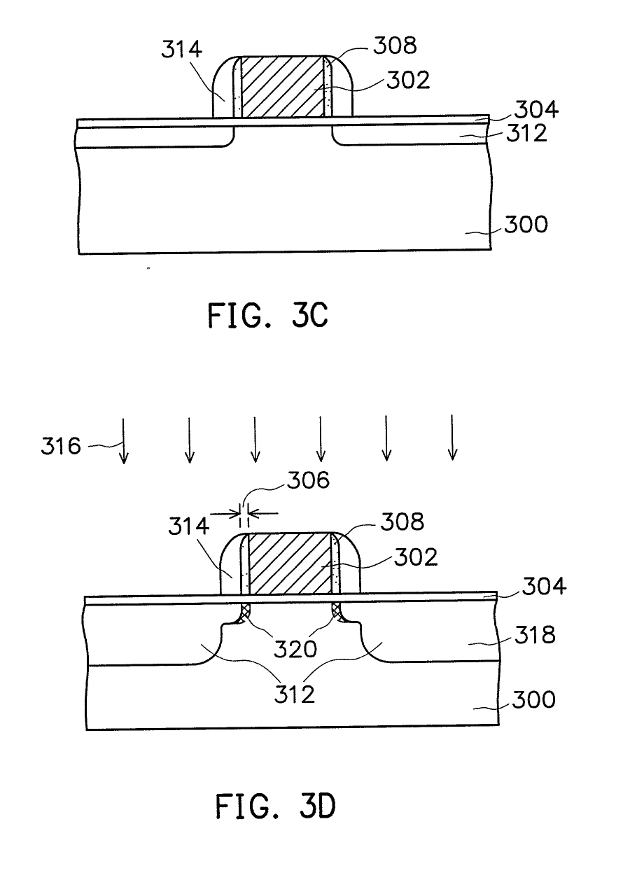

FIGS. 3A through 3D are schematic, cross-sectional views showing the progression of manufacturing steps for producing a semiconductor device according to a second preferred embodiment of the invention.

As shown in FIG. 3A, a substrate 300 having a gate oxide layer 304 and a gate electrode 302 is provided. Thereafter, first spacers 308 are formed on the sidewalls of the gate electrode 302. Thickness 306 of the first spacers 308 depends on the required channel length. Preferably, the first spacers 308 are made from silicon nitride material. The first spacers 308 are formed, for example, by depositing a layer of dielectric material over the substrate 300 using a chemical vapor deposition (CVD) method, and then performing an anisotropic etching operation to etch back the dielectric layer.

A first ion implantation 310 is carried out implanting, for example, arsenic or phosphorus ions into the substrate 300 to form lightly doped regions 312 as shown in FIG. 3B. Concentration of ions in the first ion implantation 310 can be adjusted according to the specific requirement. Consequently, a source/drain region having a lightly doped drain (LDD) structure, moderately doped drain (MDD) structure or a heavily doped drain (HDD) structure are obtained.

As shown in FIG. 3C, a second spacer 314 is formed on each exterior sidewall of the first spacers 308. Preferably, the second spacers 314 are made from silicon dioxide material. The second spacers 314 are formed, for example, by depositing a layer of silicon dioxide over the substrate 300 using a chemical vapor deposition (CVD) method, and then performing an anisotropic etching operation to etch back the dielectric layer.

As shown in FIG. 3D, using both the first spacers 308, the second spacers 314 and the gate electrode 302 as a mask, a second ion implantation 316 is performed. Finally, source/drain regions 318 each having a lightly doped drain region 312 are formed.

Due to thermal operations, ions within the lightly doped drain region 312 may travel a little distance inside the substrate. However, the distance of travel is usually small. Hence, with a first spacer on the side of the gate electrode 302, the ions have to travel a little extra distance before they can reach the substrate area 300 underneath the gate electrode 302. In other words, the number of ions that can diffuse into the substrate area 300 underneath the gate electrode 302 is greatly reduced (label 320 in FIG. 3D). Hence, gate-to-drain capacitance (Cgd) formed by the elements that include the gate electrode 302, the gate oxide layer 304 and the lightly doped drain region 312 can be reduced considerably. Furthermore, by controlling the thickness 306 of the first spacer 308, length of the channel can be adjusted to reduce the short channel effect.

In summary, the advantages of this invention according to the first embodiment includes:

1. The sidewall-attached portion of the dielectric layer can serve as a mask to shield the channel area in the substrate from any ions in the first ion implantation. Hence, the substrate underneath it is not be doped. Moreover, after the formation of the lightly doped drain regions, dopants in the lightly doped drain region can travel only a short distance. Since the dielectric layer has a definite thickness, ions in the lightly doped drain regions are unable to diffuse far enough into the substrate area underneath the gate electrode. Consequently, gate-to-drain capacitance can be greatly reduced.

2. By controlling the thickness of the dielectric layer, a channel having the proper length can be formed under the gate electrode. Hence, the short channel effect can be prevented.

3. The gate electrode and the substrate are covered by the dielectric layer. When the first or the second ion implantation is carried out, the dielectric layer is able to prevent any damages to the substrate and gate oxide layer due to the bombardment ions. In other words, defects in the substrate are reduced. In addition, trapped ions within the gate oxide layer that can possibly lead to the production of a leakage current are reduced, as well.

The advantages of this invention according to the second embodiment includes:

1. The first spacers on the sidewalls of the gate electrode can serve as a mask during the first ion implantation for preventing any ions from entering the substrate. Since ions in the lightly doped region are able to diffuse only a short distance, the extra distance caused by the additional first spacer is able to minimize the number of ions entering the substrate area underneath the gate electrode. Hence, the gate-to-drain capacitance (Cgd) problem is greatly reduced.

2. By controlling the thickness of the first spacers, a channel having the proper length can be formed under the gate electrode. Hence, the short channel effect can be prevented.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method for manufacturing a semiconductor device, comprising the steps of:
providing a substrate having a gate electrode thereon;
forming a dielectric layer having a definite thickness over the substrate and the gate electrode;
performing a first ion implantation using the gate electrode and a portion of the dielectric layer next to the sidewalls of the gate electrode as a mask, thereby forming a doped region in the substrate on each side of the gate electrode and a channel in the substrate underneath the gate electrode;
forming a spacer over the portion of the exposed dielectric layer next to the sidewalls of the gate electrode; and
performing a second ion implantation using the gate electrode, the portion of the dielectric layer next to the sidewalls of the gate electrode and the spacers as a mask, thereby forming source/drain regions in the substrate.

2. The method of claim 1, wherein length of the channel can be adjusted by changing the thickness of the dielectric layer.

3. The method of claim 1, wherein the step of forming the dielectric layer includes depositing silicon nitride.

4. The method of claim 1, wherein the step of forming the doped region includes implanting heavily to form a heavily doped drain region.

5. The method of claim 1, wherein the step of forming the doped region includes implanting lightly to form a lightly doped drain region.

6. The method of claim 1, wherein the step of forming the doped region includes implanting moderately to form a moderately doped drain region.

7. A method for manufacturing semiconductor device, comprising the steps of:
providing a substrate having a gate electrode thereon;
forming first spacer having a definite thickness on the sidewalls of the gate electrode;
performing a first ion implantation using the gate electrode and the first spacers as a mask, thereby forming a doped region in the substrate on each side of the gate electrode and a channel in the substrate underneath the gate electrode;
forming a second spacer over the exterior sidewalls of each first spacers; and
performing a second ion implantation using the gate electrode, the first spacers and the second spacers as a mask, thereby forming source/drain regions in the substrate.

8. The method of claim 7, wherein length of the channel can be adjusted by changing the thickness of the first spacers.

9. The method of claim 7, wherein the step of forming the first spacers includes depositing silicon nitride.

10. The method of claim 7, wherein the step of forming the doped region includes implanting heavily to form a heavily doped drain region.

11. The method of claim 7, wherein the step of forming the doped region includes implanting lightly to form a lightly doped drain region.

12. The method of claim 7, wherein the step of forming the doped region includes implanting moderately to form a moderately doped drain region.
